(19) United States
(12) Patent Application Publication
(10) Pub. No.: US 2004/0038148 A1
(43) Pub. Date: Feb. 26, 2004

(54) Positive type radiation-sensitive resin composition for producing product formed by plating and process for producing product formed by plating

(75) Inventors: Masaru Ohta, Tokyo (JP); Atsushi Ito, Tokyo (JP); Shin-Ichiro Iwanaga, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: JSR CORPORATION, Tokyo (JP)

(21) Appl. No.: 10/224,608

(22) Filed: Aug. 21, 2002

(51) Int. Cl. G03F 7/039; G03F 7/40

(52) U.S. Cl. 430/270.1; 430/315

(57) ABSTRACT

The present invention provides a positive type radiation-sensitive resin composition for producing a product formed by plating, which is capable of forming a product formed by plating of a thick film such as a bump or a wiring with high precision and has excellent sensitivity and resolution, and a process for producing a product formed by plating using the composition. The positive type radiation-sensitive resin composition for producing a product formed by plating comprises (A) a polymer having an acid-dissociative functional group which is dissociated by an acid to generate an acid functional group and (B) a component which generates an acid when irradiated with a radiation. This composition is used also for a positive type radiation-sensitive resin film. The product formed by plating is produced by a process including a step wherein electroplating is carried out with the use of a pattern that is formed from the composition or the resin film on the substrate as a mold.

### BACKGROUND OF THE INVENTION

1. Field of the Invention

The present invention relates to a positive type radiation-sensitive resin composition for producing a product formed by plating and a process for producing a product formed by plating. More particularly, the invention relates to a positive type radiation-sensitive resin composition for producing a product formed by plating, which contains a polymer having an acid-dissociative functional group, and a process for producing a product formed by plating for use as a bump, a wiring or the like when an integrated circuit element is mounted, using the positive type radiation-sensitive resin composition for producing a product formed by plating.

2. Description of Background Art

With miniaturization of integrated circuit elements, high integration of large-scale integrated circuits (LSI) and shifting to integrated circuits suited to specific purposes, which are called ASIC, have rapidly proceeded in recent years. On this account, multi-pin thin film mounting to mount LSI on the electronic equipment has been required, and there has been adopted bare chip mounting by the tape automated bonding (TAB) method or the flip-chip method. In the multi-pin thin film mounting, it is necessary to precisely arrange a protruding electrode having a height of 10 μm or above, which is called a bump, as a connecting terminal on the substrate, and besides, more precise arrangement of the bump is required to cope with much higher integration of LSI in the future.

The bump is now produced in the following procedure. On a wafer provided with a LSI element, a barrier metal is laminated to form a conductive layer, and a radiation-sensitive resin composition, i.e., a resist, is applied there on and dried. Then, the resist is irradiated with a radiation (referred to as “exposure” hereinafter) through a mask in order to open the area for a bump, and then developed to form a pattern. Thereafter, the electrode material such as gold or copper is deposited by electroplating with the use of the pattern as a mold. Then, the resin is removed, and the barrier metal is removed by etching. Thereafter, chips is squarely cut off from the wafer, followed by packaging with the use of TAB or mounting such as flip-chip mounting.

In a series of the above-mentioned steps for forming a bump, the resist needs to have following properties.

1. A coating film of a uniform thickness of 20 μm or above can be formed.

2. In order to cope with narrowing of a pitch of a bump, the resist has high resolution.

3. The sidewall of a pattern used as a mold is nearly perpendicular, and the pattern has high fidelity to the mask dimension.

4. In order to enhance production efficiency of the process, the resist has high sensitivity and good developing properties.

5. The resist has good wettability by a plating solution.

6. Deterioration of a plating solution is not caused by elution of the resist component into the plating solution in the plating stage.

7. The resist has high adhesion to the substrate so that the plating solution should not ooze on the interface between the substrate and the resist in the plating stage.

8. After plating, the resist can be readily removed by a remover.

9. The configuration of the pattern used as a mold is transferred to the resulting plating deposit with high fidelity, and the plating deposit has high fidelity to the mask dimension.

As the resist for forming a bump, a negative type radiation-sensitive resin composition containing as main components a novolak resin and a naphthoquinonediazido group-containing compound (Japanese Patent Laid-Open Publication No. 207067/1998) has been heretofore used. By the use of this resist, obtainable is a forward tapered shape as a pattern configuration, and a pattern having a perpendicular sidewall cannot be obtained. Moreover, because of low sensitivity, the exposure time is prolonged, resulting in a problem of low production efficiency. In addition, this resist is not satisfactory in the resolution and the fidelity of a plating deposit of a thick film to the mask dimension.

### SUMMARY OF THE INVENTION

In order to solve the above problems in the background art, studies have been eagerly made regarding the components of a radiation-sensitive resin composition used as a resist for producing a bump or the like, and as a result, the present invention has been accomplished. It is an object of the invention to provide a positive type radiation-sensitive resin composition for producing a product formed by plating, which is capable of forming a product formed by plating of a thick film such as a bump or a wiring with high precision and is excellent in sensitivity, resolution and the like, and a process for producing a product formed by plating using the positive type radiation-sensitive resin composition.

First, the object of the invention has been achieved by a positive type radiation-sensitive resin composition for producing a product formed by plating, comprising (A) a polymer having an acid-dissociative functional group which is dissociated by an acid to generate an acid functional group and (B) a component which generates an acid when exposed.

Secondly, the object of the invention has been achieved by a process for producing a product formed by plating, comprising (a) a step of forming a resin film wherein the above-mentioned positive type radiation-sensitive resin composition for producing a product formed by plating is applied on to a substrate having a conductive layer on its surface and then dried, (b) a step of forming a pattern wherein the resin film is exposed in a given pattern configuration, then heated and developed, (c) a step wherein a product formed by plating is formed in a given thickness by electroplating with the use of the pattern formed on the substrate as a mold, (d) a step wherein the resin film is removed from the substrate, and (e) a step wherein the conductive layer present on the area of the substrate other than the area where the product formed by plating has been formed is removed.

Thirdly, the object of the invention has been achieved by a positive type radiation-sensitive resin film for producing a product formed by plating, comprising a resin film formed by applying a positive type radiation-sensitive resin composition for producing a product formed by plating onto a support film, drying the composition and then peeling the support film, said composition comprising (A) a polymer having an acid-dissociative functional group which is dissociated by an acid to generate an acid functional group and (B) a component which generates an acid when exposed.

Fourthly, the object of the invention has been achieved by a process for producing a product formed by plating, comprising (a) a step wherein the above-mentioned positive type radiation-sensitive resin film for producing a product formed by plating is laminated on a substrate having a conductive layer on its surface, (b) a step of forming a pattern wherein the resin film laminated is exposed in a given pattern configuration, then heated and developed, (c) a step wherein a product formed by plating is formed in a given thickness by electroplating with the use of the pattern formed on the substrate as a mold, (d) a step wherein the resin film is removed from the substrate, and (e) a step wherein the conductive layer present on the area of the substrate other than the area where the product formed by plating has been formed is removed.

In the present invention, a component which generates an acid when exposed (referred to as a “radiation-sensitive acid generating agent” hereinafter) is contained in the positive type radiation-sensitive resin composition used for producing a product formed by plating, and when this component is exposed, an acid is generated. By virtue of the catalytic action of this acid, chemical reaction (e.g., change of polarity, decomposition of chemical bond, crosslinking reaction) is brought about in the resin film (i.e., resist film) comprising the positive type radiation-sensitive resin composition, whereby the solubility of the resin film in the developer is changed in the exposed portion. By the utilization of this phenomenon, a pattern is formed.

The mechanism of the formation of the pattern is as follows. By the catalytic action of the acid generated by the exposure of the radiation-sensitive acid generating agent, the acid-dissociative functional group in the acid-dissociative functional group-containing polymer contained in the positive type radiation-sensitive resin composition is dissociated to generate an acid functional group, and as a result, the solubility of the polymer in an alkaline developer is increased in the exposed portion. The dissociation of the acid-dissociative functional group is promoted by heating (Post Exposure Bake, referred to as “PEB” hereinafter) after the exposure. The acid that is newly generated by the dissociation of the acid-dissociative functional group exerts catalytic action on the next dissociation. Thus, dissociation of the acid-dissociative functional group and generation of an acid are “amplified” one after another. By the utilization of the chemical amplification action, a prescribed pattern is formed with high sensitivity (i.e., the small exposure amount) and high resolution.

### DETAILED DESCRIPTION OF THE INVENTION

The present invention is described in detail hereinafter.

Polymer (A)

The polymer having an acid-dissociative functional group which is dissociated by an acid to generate an acid functional group (referred to as a “polymer (A)” hereinafter), said polymer being for use in the invention, is not specifically limited as long as the polymer has an acid-dissociative functional group which is dissociated by an acid to generate an acid functional group such as a carboxyl group or a phenolic hydroxyl group. However, preferable is a polymer containing a repeating unit (referred to as an “acid-dissociative repeating unit” hereinafter) formed by cleavage of a polymerizable unsaturated bond of a radical polymerizable monomer having the acid-dissociative functional group (referred to as a “monomer (I)” hereinafter).

Of the acid-dissociative repeating units, the repeating unit which is dissociated by an acid to generate a carboxyl group is, for example, a unit formed by cleavage of a polymerizable unsaturated bond of a monomer such as t-butyl(meth)acrylate, tetrahydropyranyl(meth)acrylate, 2-t-butoxycarbonylmethyl(meth)acrylate, 2-benzyloxycarbonylethyl(meth)acrylate, 2-methyladamantyl(meth)acrylate, 1,1-dimethyl-3-oxobutyl(meth)acrylate or t-butoxycarbonylmethoxystyrene, or a repeating unit represented by the following formula (1) (referred to as a “repeating unit (1)” hereinafter).

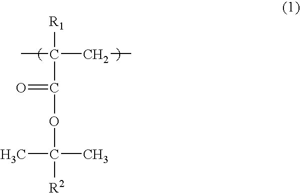

In the formula (1), R¹ is a hydrogen atom or a methyl group, and R² is a monovalent alicyclic group of 6 to 20 carbon atoms which may have a substituent or a monovalent aromatic group of 6 to 20 carbon atoms which may have a substituent.

Examples of the monovalent alicyclic groups of 6 to 20 carbon atoms which may have a substituent, said groups being indicated by R² in the formula (1), include cyclohexyl, cycloheptyl, cyclooctyl, 2-methylcyclohexyl, 3-methylcyclohexyl, 4-methylcyclohexyl, 4-chlorocyclohexyl, 4-t-butylcyclohexyl, norbornyl, isobornyl, adamantly, 2-methyladamantyl and tricylodecanyl.

Examples of the monovalent aromatic groups of 6 to 20 carbon atoms which may have a substituent, said groups being indicated by R², include phenyl, o-tolyl, m-tolyl, p-tolyl, 4-chlorophenyl, 4-t-butylphenyl, 1-naphthyl and benzyl.

Examples of the repeating units which are dissociated by an acid to generate a phenolic hydroxyl group include units formed by cleavage of polymerizable unsaturated bonds of hydroxystrenes protected by an acetal group such as p-1-methoxyethoxystyrene and p-1-ethoxyethoxystyrene, t-butoxystyrene, t-butoxycarbonyloxystyrene and the like.

With respect to the polymer (A), the acid-dissociative functional group in the acid-dissociative repeating unit is dissociated by an acid to generate an acid functional group, and additionally, an acid dissociation substance is generated by the dissociation. For example, when the repeating unit (1) is a repeating unit derived from 2-benzylpropyl (meth) acrylate, 2-benzylpropene is generated.

If the boiling point at 1 atm (referred to as a “boiling point” simply hereinafter) of the acid dissociation substance is not higher than room temperature, the substance may give an evil influence on the pattern configuration in the production of a product formed by plating.

When the thickness of the resist film is in the range of about 1 to 2 μm as in the case of forming a circuit of an integrated circuit element, the acid dissociation substance generally permeates as a gas component through the resist film during the stage of PEB even if the substance has a boiling point of lower than 20° C., thus in practice, the substance gives no influence on the pattern configuration. However, the resist film for producing a bump or the like occasionally needs to have a thickness of 20 μm or above. In this case, the gas component generated remains in the resist film to form large bubbles, thus the bubbles may markedly impair the pattern configuration in the developing stage. Therefore, if the acid dissociation substance has a low boiling point, particularly a boiling point of lower than 20° C., it is difficult to use the composition for such uses that the thickness of the resist film exceeds 20 μm.

As the acid-dissociative repeating unit in the polymer (A), therefore, a unit that generates an acid dissociation substance having a boiling point of 20° C. or above, more specifically, a repeating unit formed by cleavage of a polymerizable unsaturated bond of 1,1-dimethyl-3-oxobutyl(meth)acrylate or the repeating unit (1) is more preferable, and a repeating unit formed by cleavage of a polymerizable unsaturated bond of 1,1-dimethyl-3-oxobutyl(meth)acrylate or 2-benzylpropyl(meth)acrylate is particularly preferable. The acid dissociation substance generated from the repeating unit derived from 1,1-dimethyl-3-oxobutyl(meth)acrylate is 4-methyl-4-pentene-3-one, and its boiling point is about 130° C. The boiling point of 2-henzylpropene is about 170° C.

With respect to the polymer (A), the acid-dissociative repeating units can be used singly or in combination of two or more kinds.

The polymer (A) may further contain repeating units (referred to as “other repeating units” hereinafter) formed by cleavage of a polymerizable unsaturated bond of a radical polymerizable monomer that is copolymerizable (referred to as a “monomer (II)” hereinafter) other than the monomer (I).

Examples of the monomers (II) include:

aromatic vinyl compounds, such as o-hydroxystyrene, m-hydroxystyrene, p-hydroxystyrene, p-isopropenylphenol, styrene, α-methylstyrene, p-methylstyrene and p-methoxystyrene;

hetero atom-containing alicyclic vinyl compounds, such as N-vinylpyrrolidone and N-vinylcaprolactam;

cyano group-containing vinyl compounds, such as acrylonitrile and methacrylonitrile;

conjugated diolefins, such as 1,3-butadiene and isoprene;

amido group-containing vinyl compounds, such as acrylamide and methacrylamide;

carboxyl group-containing vinyl compounds, such as acrylic acid and methacrylic acid; and

(meth)acrylates, such as methyl(meth)acrylate, ethyl(meth)acrylate, n-propyl(meth)acrylate, n-butyl(meth)acrylate, 2-hydroxyethyl(meth)acrylate, 2-hydroxypropyl(meth)acrylate, polyethylene glycol mono (meth) acrylate, polypropylene glycol mono (meth) acrylate, glycerol mono(meth)acrylate, phenyl(meth)acrylate, benzyl(meth)acrylate, cyclohexyl(meth)acrylate, isobornyl(meth)acrylate and tricyclodecanyl(meth)acrylate.

Of the above monomers (II), preferable are p-hydroxystyrene, p-isopropenyphenol, styrene, acrylic acid, methacrylic acid, methyl(meth)acrylate, ethyl(meth)acrylate, n-butyl(meth)acrylate, 2-hydroxyethyl(meth)acrylate, 2-hydroxypropyl(meth)acrylate, benzyl(meth)acrylate and isobornyl(meth)acrylate.

The monomers (II) can be used singly or in combination of two or more kinds.

The ratio between the acid-dissociative repeating units and other repeating units in the polymer (A) is not specifically limited to extent not detrimental to the prescribed effects of the present invention, and the acid-dissociative repeating unit/other unit ratio by weight is in the range of usually 5/95 to 100/0, preferably 10/90 to 90/10, more preferably 20/80 to 80/20. If the content of the acid-dissociative repeating unit is less than 5% by weight, the proportion of the acid functional group generated becomes low, and the solubility of the resulting polymer in an alkaline developer is decreased. As a result, pattern formation may become difficult.

The polymer (A) can be prepared by, for example, the following processes.

(i) The monomer (I) is directly polymerized preferably together with the monomer (II).

(ii) After copolymerization of the monomer (I), p-acetoxystyrene, and optionally, the monomer (II), hydrolysis is carried out under the basic conditions to convert the acetoxy group in the polymer into a hydroxyl group.

(iii) After polymerization of p-t-butoxystyrene, hydrolysis is carried out under the acid conditions to convert it into poly(p-hydroxystrene), and then at least a part of hydroxyl groups in the poly(p-hydroxystyrene) are protected by, for example, t-butoxycarbonyloxy groups or 1-ethoxyethoxy groups.

The polymerization in the processes (i) to (iii) can be performed by appropriate polymerization, such as emulsion polymerization, suspension polymerization, solution polymerization or bulk polymerization, using a usual radical polymerization initiator. The solution polymerization is particularly preferable.

Examples of the radical polymerization initiators include azo compounds, such as 2,2′-azobisisobutyronitrile (AIBN) and 2,2′-azobis-(2,4-dimethylvaleronitrile); and organic peroxides, such as benzoyl peroxide, lauryl peroxide and t-butyl peroxide.

There is no specific limitation on the solvent for use in the solution polymerization, and any solvent is employable provided that the solvent is unreactive to the monomer components used and dissolves the resulting polymer. Examples of such solvents include methanol, ethanol, n-hexane, toluene, tetrahydrofuran, 1,4-dioxane, ethyl acetate, n-butyl acetate, acetone, methyl ethyl ketone, methyl isobutyl ketone, 2-heptanone, cyclohexanone, ethylene glycol monomethyl ether, propylene glycol monomethyl ether, propylene glycol monomethyl ether acetate, methyl 3-methoxypropionate, ethyl 3-ethoxypropionate, ethyl lactate and y-butyrolactone.

These solvents can be used singly or in combination of two or more kinds.

When the polymer (A) is prepared by the solution polymerization, the resulting polymer solution may be used as it is in the preparation of a positive type radiation-sensitive resin composition, or after separation of the polymer (A) from the polymer solution, the polymer (A) may be used in the preparation of a positive type radiation-sensitive resin composition.

In the polymerization of the processes (i) to (iii), a molecular weight modifier such as a mercaptan compound or a halogenated hydrocarbon can be used when needed.

The molecular weight of the polymer (A) can be controlled by properly selecting the polymerization conditions, such as monomer composition, radical polymerization initiator, molecular weight modifier and polymerization temperature, and the weight-average molecular weight (Mw) of the polymer (A) in terms of polystyrene is in the range of usually 5,000 to 200,000, preferably 7,000 to 100,000. If the Mw of the polymer (A) is less than 5,000, strength of the polymer is lowered, so that the plating resistance of the resin film may become insufficient. On the other hand, if the Mw exceeds 200,000, alkali solubility of the polymer after the exposure is decreased, so that the formation of fine pattern tends to become difficult.

In the present invention, the polymer (A) can be used singly or in combination of two or more kinds.

Acid Generating Agent (B)

The radiation-sensitive acid generating agent (referred to as an “acid generating agent (B)” hereinafter) for use in the invention is a compound which generates an acid when exposed, and by the action of the acid, the acid-dissociative functional group present in the polymer (A) is dissociated to generate an acid functional group such as a carboxyl group or a phenolic hydroxyl group. As a result, the exposed portion of the resin film formed from the positive type radiation-sensitive resin composition has solubility in an alkaline developer, and a positive pattern can be formed.

The acid generating agent (B) is, for example, an onium salt compound (including a thiophenium salt compound), a halogen-containing compound, a diazoketone compound, a sulfone compound, a sulfonic acid compound, a sulfonimide compound or a diazomethane compound. Examples of these compounds are given below.

Onium Salt Compound

The onium salt compound is, for example, an iodonium salt, a sulfonium salt, a phosphonium salt, a diazonium salt or a pyridinium salt.

Preferred examples of the onium salt compounds include diphenyliodonium trifluoromethanesulfonate, diphenyliodonium p-toluenesulfonate, diphenyliodonium hexafluoroantimonate, diphenyliodonium hexafluorophosphate, diphenyliodonium tetrafluoroborate, triphenylsulfonium trifluoromethanesulfonate, triphenyl hexafluoroantimonate, triphenylsulfonium hexafluorophsphate, 4-t-butylphenyl.diphenylsulfonium trifluoromethanesulfonate, 4-t-butylphenyl.diphenylsulfonium perfluoro-n-octanesulfonate, 4-t-butylphenyl.diphenylsulfonium pyrenesulfonate, 4-t-butylphenyl.diphenylsulfonium n-dodecylbenzenesulfonate, 4-t-butylphenyi.diphenylsulfonium p-toluenesulfonate, 4-t-butylphenyl.diphenylsulfonium benzenesulfonate and 4,7-di-n-butoxynaphthyltetrahydrothiophenium trifluoromethanesulfonate.

Halogen-Containing Compound

The halogen-containing compound is, for example, a haloalkyl group-containing hydrocarbon compound or a haloalkyl group-containing heterocyclic compound.

Preferred examples of the halogen-containing compounds include 1,10-dibromo-n-decane, 1,1-bis(4-chlorophenyl)-2,2,2-trichloroethane, and (trichloromethyl)-s-triazine derivatives, such as phenyl-bis(trichloromethyl)-s-triazine, 4-methoxyphenyl-bis(trichloromethyl)-s-triazine, styryl-bis(trichloromethyl)-s-triazine and naphthyl-bis(trichloromethyl)-s-triazine.

Diazoketone Compound

The diazoketone compound is, for example, a 1,3-diketo-2-diazo compound, a diazobenzoquinone compound or a diazonaphthoquinone compound.

Preferred examples of the diazoketone compounds include esters of phenols and 1,2-naphthoquinonediazido-4-sulfonic acid, and esters of phenols and 1,2-naphthoquinonediazido-5-sulfonic acid.

Sulfone Compound

The sulfone compound is, for example, β-ketosulfone, β-sulfonylsulfone, or an α-diazo compound thereof.

Preferred examples of the sulfone compounds include 4-trisphenacylsulfone, mesitylphenacylsulfone and bis(phenylsulfonyl)methane.

Sulfonic Acid Compound

The sulfonic acid compound is, for example, an alkylsulfonic acid ester, a haloalkylsulfonic acid ester, an arylsulfonic acid ester or an iminosulfonate.

Preferred examples of the sulfonic acid compounds include benzoin tosylate, pyrogallol tristrifluoromethanesulfonate, o-nitrobenzyl trifluoromethanesulfonate and o-nitrobenzyl-p-toluene sulfonate.

Sulfonimide Compound

Preferred examples of the sulfonimide compounds include:

N-(trifluoromethylsulfonyloxy)succinimide,

N-(trifluoromethylsulfonyloxy)phthalimide,

N-(trifluoromethylsulfonyloxy)diphenylmaleimide,

N-(trifluoromethylsulfonyloxy)bicyclo[2.2.1]hept-5-ene-2,3-dicarboxyimide,

N-(trifluoromethylsulfonyloxy)-7-oxabicyclo[2.2.1]hept-5-ene-2,3-dicarboxyimide,

N-(trifluoromethylsulfonyloxy)bicyclo[2.2.1]heptan-5,6-oxy-2,3-dicarboxyimide,

N-(trifluoromethylsulfonyloxy)naphthylimide,

N-(4-methylphenylsulfonyloxy)succinimide,

N-(4-methylphenylsulfonyloxy)phthalimide,

N-(4-methylphenylsulfonyloxy)diphenylmaleimide,

N-(4-methylphenylsulfonyloxy)bicyclo[2.2.1]hept-5-ene-2,3-dicarboxyimide,

N-(4-methylphenylsulfonyloxy)-7-oxabicyclo[2.2.1]hept-5-ene-2,3-dicarboxyimide,

N-(4-methylphenylsulfonyloxy)bicyclo[2.2.1]heptan-5,6-oxy-2,3-dicaboxyimide,

N-(4-methylphenylsulfonyloxy)naphthylimide,

N-(2-trifluoromethylphenylsulfonyloxy)succinimide,

N-(2-trifluoromethylphenylsulfonyloxy)phthalimide,

N-(2-trifluoromethylphenylsulfonyloxy)diphenylmaleimide,

N-(2-trifluoromethylphenylsulfonyloxy)bicyclo[2.2.1]hept-5-ene-2,3-dicarboxyimide,

N-(2-trifluoromethylphenylsulfonyloxy)-7-oxabicyclo[2.2.1]hept-5-ene-2,3-dicarboxyimide,

N-(2-trifluoromethylphenylsulfonyloxy)bicyclo[2.2.1]heptan-5,6-oxy-2,3-dicaboxyimide,

N-(2-trifluoromethylphenylsulfonyloxy)naphthylimide,

N-(4-fluorophenylsulfonyloxy)succinimide,

N-(4-fluorophenylsulfonyloxy)-7-oxabicyclo[2.1.1]hept-5-ene-2,3-dicarboxyimide,

N-(4-fluorophenylsulfonyloxy)bicyclo[2.1.1]heptan-5,6-oxy-2,3-dicaboxyimide,

N-(4-fluorophenylsulfonyloxy)naphthylimide, and

N-(10-camphorsulfonyloxy)naphthylimide.

Diazomethane Compound

Preferred examples of the diazomethane compounds include

bis(trifluoromethylsuifonyl)diazomethane,

bis(cyclohexylsulfonyl)diazomethane,

bis(phenylsulfonyl)diazomethane,

bis(p-toluenesulfonyl)diazomethane,

methylsulfonyl-p-toluenesulfonyldiazomethane,

cyclohexylsulfonyl-1,1-dimethylethylsulfonyldiazomethane and bis(1,1-dimethylethylsulfonyl)diazomethane.

Of these acid generating agents (B), still preferable are 4-t-butylphenyl.diphenylsulfonium trifluoromethanesulfonate, 4-t-butylphenyl.diphenylsufonium perfluoro-n-octanesulfonate, 4-t-butylphenyl.diphenylsulfonium pyrenesulfonate and 4,7-di-n-butoxynaphthyltetrahydrothiophenium trifluoromethanesulfonate, and particularly preferable are 4-t-butylphenyl.diphenylsulfonium trifluoromethanesulfonate and 4,7-di-n-butoxynaphthyltetrahydrothiophenium trifluoromethanesulfonate.

In the present invention, the acid generating agent (B) can be used singly or in combination of two or more kinds.

From the viewpoint of ensuring sensitivity, resolution and pattern configuration of the resist, the acid generating agent (B) is used in an amount of usually 0.1 to 20 parts by weight, preferably 0.3 to 10 parts by weight, based on 100 parts by weight of the polymer (A). If the amount of the acid generating agent (B) is less than 0.1 part by weight, the sensitivity and the resolution tend to be lowered. On the other hand, if the amount thereof exceeds 20 parts by weight, transparency to the radiation is decreased, and thereby the pattern configuration tends to be deteriorated.

Acid Diffusion Inhibitor

To the positive type radiation-sensitive resin composition of the invention, an acid diffusion inhibitor to control diffusion into the resin film of the acid generated from the acid generating agent (B) and to inhibit undesirable chemical reaction in the unexposed portion is preferably added. By the use of the acid diffusion inhibitor, storage stability of the composition is improved, and resolution of the resist is further enhanced. Moreover, change in the line width of the pattern due to variation of the period of holding time between the exposure and the PEB can be inhibited, so that the processing stability becomes remarkably excellent.

The acid diffusion inhibitor is preferably a nitrogen-containing organic compound whose basicity is not changed by the exposure or the heating in the process for producing a product formed by plating.

Examples of the acid diffusion inhibitors include n-hexylamine, n-heptylamine, n-octylamine, n-nonylamine, ethylenediamine, N,N,N′,N′-tetramethylethylenediamine, tetramethylenediamine, hexamethylenediamine, 4,4′-daminodiphenylmethane, 4,4′-diaminodiphenyl ether, 4,4′-diaminobenzophenone, 4,4′-diaminodiphenylamine, formamide, N-methylformamide, N,N-dimethylformamide, acetamide, N-methylacetamide, N,N-dimethylacetamide, propionamide, benzamide, pyrrolidone, N-methylpyrrolidone, methylurea, 1,1-dimethylurea, 1,3-dimethylurea, 1,1,3,3-tetramethylurea, 1,3-diphenylurea, imidazole, benzimidazole, 4-methylimidazole, 8-oxyquinoline, acridine, purine, pyrrolidine, piperidine, 2,4,6-tri(2-pyridyl)-s-triazine, morpholine, 4-methylmorpholine, piperazine, 1,4-dimethylpiperazine and 1,4-diazabicyclo[2.2.2]octane.

Of these nitrogen-containing organic compounds, 2,4,6-tri(2-pyridyl)-s-triazine is particularly preferable.

The acid diffusion inhibitors mentioned above can be used singly or in combination of two or more kinds.

The acid diffusion inhibitor is used in an amount of usually not more than 15 parts by weight, preferably 0.001 to 10 parts by weight, more preferably 0.005 to 5 parts by weight, based on 100 parts by weight of the polymer (A). If the amount of the acid diffusion inhibitor exceeds 15 parts by weight, sensitivity of the resist and developing properties of the exposed portion tend to be lowered. On the other hand, if the amount thereof is less than 0.001 part by weight, pattern configuration or dimensional fidelity of the resist may be deteriorated depending upon the processing conditions.

Other Alkali-Soluble Resins

To the positive type radiation-sensitive resin composition of the invention, alkali-soluble resins other than the polymer (A) (referred to as “other alkali-soluble resins” hereinafter) can be added according to circumstances.

Other alkali-soluble resins are resins which have one or more kinds of functional groups exhibiting affinity for an alkaline developer, for example, an acid functional group such as a phenolic hydroxyl group or a carboxyl group and are soluble in an alkaline developer. By the addition of such an alkali-soluble resin, the rate at which the resin film formed from the positive type radiation-sensitive resin composition is dissolved in an alkaline developer can be more easily controlled, and as a result, developing properties can be further enhanced.

Other alkali-soluble resins are not specifically limited as long as the resins are soluble in an alkaline developer. Preferred examples of other alkali-soluble resins include an addition polymerization type resin containing a repeating unit formed by cleavage of a polymerizable unsaturated bond of at least one monomer having an acid functional group, such as o-hydroxsytyrene, m-hydroxystyrene, p-hydroxystyrene, p-isopropenylphenol, p-vinylbenzoic acid, p-carboxymethylstyrene, p-carboxymethoxystyrene, acrylic acid, methacrylic acid, crotonic acid, maleic acid, fumaric acid, itaconic acid, citraconic acid, mesaconic acid or cinnamic acid, and a polycondensation type resin containing a condensation type repeating unit having an acid functional group, such as a novolak resin.

The alkali-soluble addition polymerization type resin may be constituted of only the repeating units formed by cleavage of polymerizable unsaturated bonds of a monomer having an acid functional group, but can further contain one or more kinds of other repeating units as long as the resulting resin is soluble in an alkaline developer. Examples of other repeating units include units formed by cleavage of polymerizable unsaturated bonds of monomers, such as styrene, α-methylstyrene, o-vinyltoluene, m-vinyltoluene, p-vinyltoluene, maleic anhydride, acrylonitrile, methacrylonitrile, crotononitrile, maleinonitrile, fumaronitrile, mesacononitrile, citracononitrile, itacononitrile, acrylamide, methacrylamide, crotonamide, maleinamide, fumaramide, mesaconamide, citraconamide, itaconamide, 2-vinylpyridine, 3-vinylpyridine, 4-vinypyridine, N-vinylaniline, N-vinyl-ε-caprolactam, N-vinylpyrrolidone and N-vinylimidazole.

From the viewpoints of high transmission of the radiation and excellent dry etching resistance with respect to the resulting resin film, the alkali-soluble addition polymerization type resin is particularly preferably a copolymer of poly(p-hydroxystyrene) and p-isopropenylphenol, or the like.

With regard to the molecular weight of the alkali-soluble addition polymerization type resin, the weight-average molecular weight (Mw) in terms of polystyrene is in the range of usually 1,000 to 200,000, preferably 5,000 to 50,000.

The alkali-soluble polycondensation type resin may be constituted of only the condensation type repeating units having an acid functional group, but can further contain other condensation type repeating units as long as the resulting resin is soluble in an alkaline developer.

The polycondensation type resin can be prepared by, for example, (co)polycondensating one or more kinds of phenols and one or more kinds of aldehydes, optionally with another polycondensation component capable of forming another condensation type repeating unit, in a water medium or a mixed medium of water and a hydrophilic solvent in the presence of an acid catalyst or a basic catalyst.

Examples of the phenols include o-cresol, m-cresol, p-cresol, 2,3-xyienol, 2,4-xylenol, 2,5-xylenol, 3,4-xylenol, 3, 5-xylenol, 2,3,5-trimethylphenol and 3,4,5-trimethylphenol. Examples of the aldehydes include formaldehyde, trioxane, paraformaldehyde, benzaldehyde, acetaldehyde, propylaldehyde and phenylacetaldehyde.

With regard to the molecular weight of the alkali-soluble polycondensation type resin, the weight-average molecular weight (Mw) in terms of polystyrene is in the range of usually 1,000 to 100,000, preferably 2,000 to 50,000.

The other alkali-soluble resins can be used singly or in combination of two or more kinds.

Such an alkali-soluble resin is used in an amount of usually not more than 200 parts by weight based on 100 parts by weight of the polymer (A).

Surface Active Agent

To the positive type radiation-sensitive resin composition of the invention, a surface active agent having a function of improving application properties and developing properties can be added.

Examples of the surface active agents include polyoxyethylene lauryl ether, polyoxyethylene stearyl ether, polyoxyethylene oleyl ether, polyoxyethylene n-octylphenol ether, polyoxyethylene n-nonylphenol ether, polyethylene glycol dilaurate and polyethylene glycol distearate.

These surface active agents can be used singly or in combination of two or more kinds.

The surface active agent is used in an amount of usually not more than 2 parts by weight based on 100 parts by weight of the polymer (A).

Other Additives

The positive type radiation-sensitive resin composition of the invention may further contain other additives, such as ultraviolet absorbing agent, sensitizer, dispersant, plasticizer, heat polymerization inhibitor to enhance storage stability and antioxidant. Of these, the ultraviolet absorbing agent is useful because it has a function of inhibiting photo reaction caused by introduction of scattered light into the unexposed portion in the exposure stage. As the ultraviolet absorbing agent, a compound having a high absorptivity coefficient in the wavelength region of ultraviolet rays used for the exposure is preferable. The organic pigment can also be used for the same purpose.

Organic Solvent

The positive type radiation-sensitive resin composition of the invention can be diluted with an organic solvent for the purpose of homogeneously mixing the polymer (A), the acid generating agent (B) and additives optionally mixed.

Examples of such organic solvents include those previously mentioned above with regard to the solution polymerization for preparing the polymer (A), and other solvents, such as dimethyl sulfoxide, acetonylacetone, isophorone and propylene carbonate.

These organic solvents can be used singly or in combination of two or more kinds.

The amount of the organic solvent can be determined in consideration of the method to apply the positive type radiation-sensitive resin composition, use application of the composition for producing a product formed by plating, etc., and the amount is not specifically limited provided that the composition can be homogeneously mixed. However, the organic solvent is used in such an amount that the content of solid in the composition is in the range of 30 to 90% by weight, preferably 40 to 80% by weight.

The positive type radiation-sensitive resin composition of the invention is used for producing a product formed by plating such as a bump or a wiring of an integrated circuit element.

Further, a resin film can be formed from the positive type radiation-sensitive resin composition of the invention by applying the composition onto a support film, then drying the composition and peeling the support film. The thus formed positive type radiation-sensitive resin film can be used for producing the same product formed by plating as described above. Examples of the methods to apply the positive type radiation-sensitive resin composition onto the support film include spin coating, roll coating, screen printing and an applicator method. The material of the support film is not specifically limited, and any of appropriate ones is employable as far as it has desirable strength.

The process for producing a product formed by plating according to the invention is described below.

The process for producing a product formed by plating using the positive type radiation-sensitive resin composition of the invention (referred to as a “production process (1)” hereinafter) comprises (a) a step of forming a resin film wherein the positive type radiation-sensitive resin composition for producing a product formed by plating is applied onto a substrate having a conductive layer on its surface and then dried, (b) a step of forming a pattern wherein the resin film is exposed in a given pattern configuration, then heated and developed, (c) a step wherein a product formed by plating is formed in a given thickness by electroplating with the use of the pattern formed on the substrate as a mold, (d) a step wherein the resin film portion is removed from the substrate, and (e) a step wherein the conductive layer present on the area of the substrate other than the area where the product formed by plating has been formed is removed.

The process for producing a product formed by plating using the positive type radiation-sensitive resin film of the invention (referred to as a “production process (2)” hereinafter) comprises (a) a step wherein the positive type radiation-sensitive resin film for producing a product formed by plating is laminated on a substrate having a conductive layer on its surface, (b) a step of forming a pattern wherein the thus laminated resin film is exposed in a given pattern configuration, then heated and developed to form a pattern, (c) a step wherein a product formed by plating is formed in a given thickness by electroplating with the use of the pattern formed on the substrate as a mold, (d) a step wherein the resin film portion is removed from the substrate, and (e) a step wherein the conductive layer present on the area of the substrate other than the area where the product formed by plating has been formed is removed.

Examples of the substrates for use in the production process (1) and the production process (2) include soda glass, quartz glass, silicon carbide, titanium carbide, zirconium carbide, boron nitride, aluminum nitride, silicon nitride, silicon, germanium, gallium-arsenic and gallium-phosphorus.

Examples of conductive materials used for forming the conductive layer on the substrate surface include aluminum, copper, silver, gold, palladium and alloys of two or more kinds of these metals (e.g., palladium-gold). The conductive layer can be formed on the substrate surface by, for example, sputtering of the conductive material.

Although the thickness of the conductive layer is not specifically limited, it is in the range of usually 200 to 10,000 Å, preferably about 500 to 2000 Å.

In the production process (1), examples of the method to apply the composition for producing a product formed by plating onto the substrate include spin coating, roll coating, screen coating and an applicator method.

In the production process (2), examples of the method to laminate the resin film for producing a product formed by plating on the substrate include adhesion bonding, a roll method and a press method.

The thickness of the resin film in the production process (1) and the production process (2) can be varied depending upon the use application of the product formed by plating. In case of a bump, the thickness of the resin film is in the range of usually 20 to 100 μm, preferably 20 to 80 μm, more preferably 20 to 50 μm, and in case of a wiring, the thickness of the resin film is in the range of usually 1 to 30 μm, preferably 3 to 30 μm, more preferably 5 to 20 μm.

Examples of the radiations used for the exposure include ultraviolet rays from low-pressure mercury lamp, high-pressure mercury lamp, metal halide lamp, g-ray stepper and i-ray stepper; far ultraviolet rays, such as KrF excimer laser and ArF excimer laser; charged particle rays, such as electron rays; and X rays, such as synchrotron radiation. Of these, a radiation having a wavelength of 150 to 500 nm is preferable.

The exposure amount varies depending upon the type of radiation, component ratio of the composition, thickness of the resin film, etc., and in case of for example ultraviolet rays from a high-pressure mercury lamp, the exposure amount is in range of usually about 1,000 to 20,000 J/m².

After the exposure, PEB is carried out to promote dissociation of the acid-dissociative functional group of the polymer (A). Although the conditions of this treatment vary depending upon the component ratio of the composition, thickness of the resin film, etc., the treatment temperature is in the range of usually 70 to 120° C., preferably 100 to 120° C., and the treatment time is in the range of about 30 seconds to 10 minutes.

Thereafter, development with an alkaline developer is carried out to dissolve and remove the exposed portion, whereby a pattern of a given configuration is formed.

Examples of the developing methods with an alkaline developer include shower development, spray development, immersion development and paddle development. The developing time is in the range of usually 1 to 30 minutes at room temperature.

Examples of the alkaline developers include alkaline aqueous solutions obtained by dissolving alkaline compounds, such as sodium hydroxide, potassium hydroxide, sodium carbonate, sodium silicate, ammonia water, ethylamine, n-propylamine, diethylamine, triethylamine, monoethanolamine, diethanolamine, triethanolamine, tetramethylammonium hydroxide, tetraethylammonium hydroxide, choline, pyrrole and piperidine, in water in a concentration of, for example, 1 to 10% by weight.

To the alkaline aqueous solution, an organic solvent such as methanol or ethanol, a surface active agent, etc., can be added in an appropriate amount.

After the development with the alkaline developer, the resulting pattern is generally washed with water and then dried.

After the development, a product formed by plating is formed in a given thickness by electroplating with the use of the pattern formed on the substrate as a mold.

Prior to the electroplating, the pattern formed from the resin film is preferably subjected to a hydrophilic treatment such as an ashing treatment with an oxygen plasma in order to enhance affinity of the pattern surface for the plating solution.

The plating solution used for the electroplating is, for example, a solution containing the same metal or alloy as previously mentioned above with regard to the conductive layer.

The electroplating conditions can be varied depending upon the composition of the plating solution, etc. In case of, for example, gold plating, the temperature is in the range of usually 40 to 70° C., preferably about 55 to 70° C., and the current density is in the range of usually 0.1 to 1 A/dm², preferably 0.2 to 0.8 A/dm².

After the plating, the product formed by plating is washed with water and dried. Then, the condition of the pattern, thickness and condition of the product formed by plating, etc., are observed, and if needed, electroplating is carried out again.

The thickness of the product formed by plating varies depending upon the use application. In case of, for example, a bump, the thickness is in the range of usually 5 to 50 μm, preferably 10 to 30 μm, more preferably 15 to 25 μm, and in case of a wiring, the thickness is in the range of usually 1 to 30 μm, preferably 3 to 20 μm, more preferably 5 to 15 μm.

Thereafter, the resin film portion is removed from the substrate. Examples of the method to remove the resin film portion include such a method that the substrate is immersed in a remover under stirring at 20 to 80° C. for 1 to 10 minutes.

The remover employable herein is, for example, a mixed solution of dimethyl sulfoxide and N,N-dimethylformamide.

After the resin film portion is removed, the conductive layer present on the area of the substrate other than the area where the product formed by plating has been formed is removed by, for example, wet etching, whereby a prescribed product formed by plating is obtained.

### EXAMPLES

The present invention is further described with reference to the following examples, but it should be construed that the invention is in no way limited to those examples. In the following examples, the terms “part(s)” and “%” mean “part(s) by weight” and “% by weight”, respectively, unless otherwise stated.

Synthesis of Polymer (A)

### Synthesis Example 1

61 g of p-acetoxystyrene, 26 g of 2-benzyl-2-propyl acrylate and 13 g of styrene were mixed with 150 g of dioxane to obtain a homogeneous solution. After a nitrogen gas was bubbled through the solution for 30 minutes, 4.5 g of AIBN was added. With continuing bubbling of a nitrogen gas, the reaction temperature was maintained at 70° C., and the polymerization was carried out for 7hours. After the polymerization was completed, the reaction solution was mixed with a large amount of hexane to solidify a polymer produced. Then, by operations of redissolving the polymer in dioxane and resolidifying the polymer in hexane were repeated several times, the unreacted monomers were removed, followed by drying at 50° C. under reduced pressure, to obtain a white polymer.

The resulting polymer was dissolved in 500 g of propylene glycol monomethyl ether, and 50 g of an ammonia aqueous solution of 25% was added. The resulting solution was stirred at 80° C. for 5 hours and then subjected to hydrolysis. Subsequently, the reaction solution was poured into a 0.2% oxalic acid aqueous solution to solidify the polymer and then washed with water, followed by drying at 50° C. under reduced pressure, to obtain a white polymer.

This polymer had Mw of 10,000, and as a result of elemental analysis, the copolymerization weight ratio between p-hydroxystyrene, 2-benzyl-2-propyl acrylate and styrene was 54:30:16. This polymer is referred to as a “polymer A-1” hereinafter.

### Synthesis Example 2

45 g of p-isopropenylphenol, 30 g of 2-benzyl-2-propyl acrylate and 25 g of methyl acrylate were mixed with 150 g of dioxane to obtain a homogeneous solution. After a nitrogen gas was bubbled through the solution for 30 minutes, 4.5 g of AIBN was added. With continuing bubbling of a nitrogen gas, the reaction temperature was maintained at 70° C., and the polymerization was carried out for 7 hours. After the polymerization was completed, the reaction solution was mixed with a large amount of hexane to solidify a polymer produced. Then, by operations of redissolving the polymer in dioxane and resolidifying the polymer in hexane were repeated several times, the unreacted monomers were removed, followed by drying at 50° C. under reduced pressure, to obtain a white polymer.

This polymer had Mw of 15,000, and as a result of elemental analysis, the copolymerization weight ratio between p-isopropenylphenol, 2-benzyl-2-propyl acrylate and methyl acrylate was 45:30:25. This polymer is referred to as a “polymer A-2” hereinafter.

### Synthesis Example 3

A white polymer was obtained in the same manner as in Synthesis Example 2, except that 30 g of p-isopropenylphenol, 20 g of 2-benzyl-2-propyl acrylate and 50 g of ethyl acrylate were used as monomers.

This polymer had Mw of 18,000, and as a result of elemental analysis, the copolymerization weight ratio between p-isopropenylphenol, 2-benzyl-2-propyl acrylate and ethyl acrylate was 30:20:50. This polymer is referred to as a“polymer A-3” hereinafter.

### Synthesis Example 4

A white polymer was obtained in the same manner as in Synthesis Example 2, except that 40 g of p-isopropenylphenol, 30 g of 2-benzyl-2-propyl acrylate, 10 g of 2-hydroxypropyl acrylate and 20 g of ethyl acrylate were used as monomers.

This polymer had Mw of 17,000, and as a result of elemental analysis, the copolymerization weight ratio between p-isopropenylphenol, 2-benzyl-2-propyl acrylate, 2-hydroxypropyl acrylate and ethyl acrylate was 40:30:10:20. This polymer is referred to as a “polymer A-4” hereinafter.

### Synthesis Example 5

A white polymer was obtained in the same manner as in Synthesis Example 2, except that 40 g of p-isopropenylphenol, 30 g of 2-benzyl-2-propyl acrylate, 20 g of 2-hydroxypropyl acrylate and 10 g of benzyl acrylate were used as monomers.

This polymer had Mw of 20,000, and as a result of elemental analysis, the copolymerization weight ratio between p-isopropenylphenol, 2-benzyl-2-propyl acrylate, 2-hydroxypropyl acrylate and benzyl acrylate was 40:30:20:10. This polymer is referred to as a “polymer A-5” hereinafter.

### Synthesis Example 6

A white polymer was obtained in the same manner as in Synthesis Example 2, except that 35 g of p-isopropenylphenol, 25 g of 2-benzyl-2-propyl acrylate, 15 g of 2-hydroxypropyl acrylate and 25 g of isobornyl acrylate were used as monomers.

This polymer had Mw of 14,000, and as a result of elemental analysis, the copolymerization weight ratio between p-isopropenylphenol, 2-benzyl-2-propyl acrylate, 2-hydroxypropyl acrylate and isobornyl acrylate was 35:25:15:25. This polymer is referred to as a “polymer A-6” hereinafter.

### Synthesis Example 7

A white polymer was obtained in the same manner as in Synthesis Example 2, except that 40 g of p-isopropenylphenol, 30 g of 2-benzyl-2-propyl acrylate, 15 g of 2-hydroxypropyl acrylate and 15 g of methyl acrylate were used as monomers.

This polymer had Mw of 20,000, and as a result of elemental analysis, the copolymerization weight ratio between p-isopropenylphenol, 2-benzyl-2-propyl acrylate, 2-hydroxypropyl acrylate and methyl acrylate was 40:30:15:15. This polymer is referred to as a “polymer A-7” hereinafter.

Synthesis of Polymer for Comparison

### Synthesis Example 8

After m-cresol and p-cresol were mixed in a weight ratio of 40:60, formalin was added, and polycondensation was carried out in a conventional way with the use of an oxalic acid catalyst to obtain a resin. Then, the resin was subjected to fractionation, and the low-molecular weight component was removed to obtain a cresol novolak resin having Mw of 15,000. This resin is referred to as a “polymer R-1” hereinafter.

### Examples 1-10

The components shown in Table 1 were mixed to obtain a homogeneous solution. Then, the solution was filtered through a Teflon membrane filter having a pore size of 3 μm to prepare a resin composition. Thereafter, a patterning substrate and a plated substrate were prepared and evaluated in the following manner.

The evaluation results are shown in Table 2.

### Comparative Example 1

A positive type light-sensitive resin composition conventionally used for forming a bump was prepared as a resin composition for comparison.

That is to say, 60 parts of the polymer R-1, 30 parts (solid content) of the following poly(vinyl methyl ether) solution, 10 parts of a phenolic polymer compound represented by the following formula (2), 20 parts of a sensitizer represented by the following formula (3), 0.1 part of BM-1000 (trade name, available from Boehringer Mannheim Chemie GmbH.) and 0.1 part of Nonion S-6 (trade name, available from Kao Corporation) as a surface active agent, and a mixed solvent of ethyl 2-hydroxypropionate and ethyl 3-ethoxypropionate (equal weight ratio) were mixed to obtain a composition having a solid content of 45%. The composition was filtered through a Teflon membrane filter having a pore size of 3 μm to prepare a resin composition for comparison. Thereafter, a patterning substrate and a plated substrate were prepared and evaluated in the following manner.

The evaluation results are set forth in Table 2.

Poly(vinyl methyl ether) Solution

In a methanol solution of poly(vinyl methyl ether) (Mw: 50,000) (available from Tokyo Kasei Kogyo Co., Ltd., concentration: 50%), the solvent was solvent-replaced with ethyl 2-hydroxypropionate using a rotary evaporator to obtain a solution having a concentration of 50%.

Phenolic Polymer Compound

Compound represented by the following formula (2)

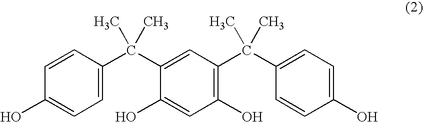

Sensitizer

Compound represented by the following formula (3) obtained by esterification reaction of 1 mol of 4,4′-[1-[4-[1-(4-hydroxyphenyl)-1-methylethyl]phenyl]ethylidene]diphenol and 2 mol of naphthoquinone-1,2-diazido-4-sulfonyl chloride.

The compound represented by the formula (3) is a mixture of a component wherein three R are each a hydrogen atom, a component wherein two R are each a hydrogen atom and one R is a naphthoquinone-1,2-diazido-4-sulfonyl group, a component wherein one R is a hydrogen atom and two R are each a naphthoquinone-1,2-diazido-4-sulfonyl group, and a component wherein three R are each a naphthoquinone-1,2-diazido-4-sulfonyl group.

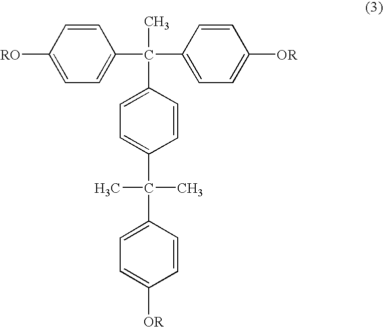

wherein each R is independently a hydrogen atom or the following group.

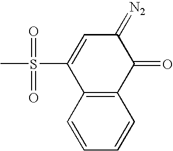

Preparation of Gold-Sputtered Substrate

On a silicon wafer substrate having a diameter of 4 inches, chromium was sputtered in a thickness of about 500 Å, and thereon gold was sputtered in a thickness of 1,000 Å to form a conductive layer. The substrate having the thus formed conductive layer is referred to as a “gold-sputtered substrate” hereinafter.

Formation of Pattern

The gold-sputtered substrate was coated with each resin composition using a spin coater and then heated on a hot plate at 90° C. for 5 minutes to form a resin film having a thickness of 25 μm. Then, the resin film was exposed to ultraviolet rays of 1,000 to 3,000 J/m² through a pattern mask by the use of an ultra-high pressure mercury lamp (HBO manufactured by OSRAM GmbH, output: 1,000 W). The exposure amount was confirmed by an illuminometer (manufactured by Orc Manufacturing Co., Ltd., obtained by connecting probe UV-35 (photodetector) to UV-M10 (illuminometer) ). After the exposure, PEB was carried out at 100° C. for 5 minutes on a hot plate. Then, the substrate was developed by immersing it in a 2.38% tetramethylammonium hydroxide aqueous solution at room temperature for 1 minute, then washed with running water and blown with nitrogen to form a pattern. The substrate having the thus formed pattern is referred to as a “patterning substrate” hereinafter.

Formation of Product Formed by Plating

The patterning substrate was subjected to an ashing treatment with an oxygen plasma (output: 200 W, oxygen flow: 200 ml, treating time: 2 minutes) as a pretreatment of electroplating to make the substrate hydrophilic. Then, the substrate was immersed in 2 liters of a non-cyanogen gold plating solution (available from N.E. Chemcat Corporation, trade name: ECF88K) to perform electroplating for about 60 minutes under the conditions of a plating bath temperature of 60° C. and a current density of 0.5 A/dm , whereby a product formed by plating (thickness: 19-20 μm) for a bump was formed. Subsequently, the thus treated substrate was washed with running water, blown with a nitrogen gas to dryness and then immersed in a mixed solution of dimethyl sulfoxide and N,N-dimethylformamide (weight ratio=50:50) for 5 minutes at room temperature to remove the resin film portion. Further, the conductive layer present on the area of the substrate other than the area where the product formed by plating had been formed was removed by wet etching, to obtain a substrate having a product formed by plating. The substrate having a product formed by plating is referred to as a “plated substrate” hereinafter.

Evaluation

(1) Sensitivity

A pattern having a pitch of 40 μm in terms of a mask design dimension (pattern of removed portion of 30 μm width/remaining portion of 10 μm width) was formed on the gold-sputtered substrate, and the exposure amount at which the dimension of the bottom of the removed portion became 30 μm was measured. The measured value was taken as an optimum exposure amount, and the sensitivity was evaluated based on the optimum exposure amount.

(2) Resolution

Two patterns having a pitch of 40 μm in terms of a mask design dimension (pattern of removed portion of 30 μm width/remaining portion of 10 μm width, and pattern of removed portion of 32 μm width/remaining portion of 8 μm width) were individually formed on the different gold-sputtered substrates. These two patterning substrates were observed by an optical microscope and a scanning electron microscope, and then evaluated based on the following criteria.

AA: A pattern of removed portion of 32 μm in width/remaining portion of 8 μm in width can be resolved.

BB: Although a pattern of removed portion of 30 μm in width/remaining portion of 10 μm in width can be resolved, a pattern of removed portion of 32 μm in width/remaining portion of 8 μm in width cannot be resolved.

CC: A pattern having a pitch of 40 μm cannot be resolved at all or cannot be resolved with high reproducibility.

(3) Dimensional Fidelity of Pattern

A patterning substrate on which a pattern having a pitch of 40 μm in terms of a mask dimension (pattern of removed portion of 30 μm width/remaining portion of 10 μm width) had been formed was observed by an optical microscope and a scanning electron microscope to measure a top dimension (Wt) and a bottom dimension (Wb) of the removed portion, and the dimensional fidelity of the pattern to the mask dimension (30 μm) was evaluated.

(4) Shape of Plated Portion

A plated substrate was obtained by forming a product formed by plating on the patterning substrate on which a pattern having a pitch of 40 μm in terms of a mask dimension (pattern of removed portion of 30 μm width/remaining portion of 10 μm width) had been formed. The plated substrate was observed by an optical microscope and a scanning electron microscope, and then evaluated based on the following criteria.

AA: The pattern configuration formed from the resin film is transferred to the plated portion with high fidelity, and no nodular abnormal protrusion is observed.

BB: The pattern configuration formed from the resin film is not transferred to the plated portion with high fidelity, and a nodular abnormal protrusion is observed.

(5) Dimensional Fidelity of Plated Portion

A plated substrate was obtained by forming a product formed by plating on the patterning substrate on which a pattern having a pitch of 40 μm in terms of a mask dimension (pattern of removed portion of 30 μm width/remaining portion of 10 μm width) had been formed. The plated substrate was observed by an optical microscope and a scanning electron microscope to measure a top dimension (Wt) and a bottom dimension (Wb) of the plated portion, and the dimensional fidelity of the plated portion to the mask dimension (30 μm) was evaluated.

In Table 1, the components other then the polymer (A) are as follows.

Acid Generating Agent (B)

B-1: 4,7-di-n-butoxynaphthyltetrahydrothiophenium trifluoromethanesulfonate

B-2: 4-t-butylphenyl diphenylsulfonium trifluoromethanesulfonate

Acid Diffusion Inhibitor

D-1: 2,4,6-tri(2-pyridyl)-s-triazine

Organic Solvent

C-1: ethyl lactate

C-2: propylene glycol monomethyl ether acetate

TABLE 1

| | | Acid generating | Acid diffusion | Organic |
|---|---|---|---|---|
| | Polymer (A) | agent (B) | inhibitor (C) | solvent |
| | (part (s)) | (part (s)) | (part (s)) | (part (s)) |
| Ex. 1 | A-1 (100) | B-1 (1) | — | C-1 (150) |
| Ex. 2 | A-1 (iQO) | B-2 (1) | — | C-1 (150) |
| Ex. 3 | A-1 (100) | B-1 (1) | — | C-2 (150) |
| Ex. 4 | A-1 (100) | B-1 (1) | D-1 (0.1) | C-1 (150) |
| Ex. 5 | A-2 (100) | B-1 (1) | — | C-1 (150) |
| Ex. 6 | A-3 (100) | B-1 (1) | — | C-1 (150) |
| Ex. 7 | A-4 (100) | B-1 (1) | — | C-1 (150) |
| Ex. 8 | A-5 (100) | B-1 (1) | — | C-1 (150) |
| Ex. 9 | A-6 (100) | B-1 (1) | — | C-1 (150) |
| Ex. 10 | A-7 (100) | B-1 (1) | — | C-1 (150) |

TABLE 2

| | | | | | Dimensional |
|---|---|---|---|---|---|
| | | | Dimensional | | fidelity of |
| | | | fidelity of | Shape of | plated |
| | Sensitivity | | pattern | plated | portion |
| | (J/m²) | Resolution | Wt/Wb (μm) | portion | Wt/Wb (μm) |
| Ex. 1 | 1,000 | AA | 30.2/29.3 | AA | 30.4/30.0 |
| Ex. 2 | 1,000 | AA | 30.4/29.7 | AA | 30.6/30.3 |
| Ex. 3 | 1,000 | AA | 30.1/29.3 | AA | 30.3/30.0 |
| Ex. 4 | 1,500 | AA | 30.1/29.8 | AA | 30.2/30.0 |
| Ex. 5 | 1,000 | AA | 31.0/29.3 | AA | 30.8/29.6 |
| Ex. 6 | 1,000 | AA | 31.4/29.8 | AA | 31.5/30.0 |
| Ex. 7 | 2,000 | AA | 30.2/29.6 | AA | 30.5/30.2 |
| Ex. 8 | 2,000 | AA | 31.4/29.9 | AA | 31.6/30.0 |
| Ex. 9 | 2,000 | AA | 30.9/29.4 | AA | 31.2/29.8 |
| Ex. 10 | 2,000 | AA | 31.1/29.5 | AA | 31.3/29.9 |
| Comp. | 6,000 | BB | 33.5/29.5 | AA | 32.9/31.1 |
| Ex. 1 | | | | | |

Effect of the Invention

By the use of the composition for producing a product formed by plating according to the invention, a pattern that is used as a mold for electroplating can be formed with high fidelity to the mask dimension, and besides, even in the electroplating step, the pattern configuration as a mold can be precisely transferred to form a product formed by plating having high fidelity to the mask dimension. Moreover, the composition has excellent sensitivity and resolution. Therefore, the composition for producing a product formed by plating according to the invention can be very preferably used for the production of a product formed by plating of a thick film such as a bump or a wiring in an integrated circuit element.

What is claimed is:

1. A positive type radiation-sensitive resin composition for producing a product formed by plating, comprising:
(A) a polymer having an acid-dissociative functional group which is dissociated by an acid to generate an acid functional group, and
(B) a component which generates an acid when irradiated with a radiation.

2. The positive type radiation-sensitive resin composition for producing a product formed by plating as claimed in claim 1, comprising:
(A) a polymer having an acid-dissociative functional group which is dissociated by an acid to generate an acid functional group,
(B) a component which generates an acid when irradiated with a radiation, and
(C) an organic solvent,
wherein the content of the component (B) is in the range of 0.1 to 20 parts by weight based on 100 parts by weight of the component (A) and the component (C) is contained in such an amount that the content of the solid in the composition is in the range of 30 to 90% by weight.

3. The positive type radiation-sensitive resin composition for producing a product formed by plating as claimed in claim 1, wherein an acid dissociation substance, which is generated by the acid dissociation of the acid-dissociative functional group in the polymer (A) having an acid-dissociative functional group which is dissociated by an acid to generate an acid functional group, has a boiling point of 20° C. or above at 1 atm.

4. The positive type radiation-sensitive resin composition for producing a product formed by plating as claimed in claim 2, wherein an acid dissociation substance, which is generated by the acid dissociation of the acid-dissociative functional group in the polymer (A) having an acid-dissociative functional group which is dissociated by an acid to generate an acid functional group, has a boiling point of 20° C. or above at 1 atm.

5. The positive type radiation-sensitive resin composition for producing a product formed by plating as claimed in claim 3, wherein a repeating unit having the acid-dissociative functional group in the polymer (A) having an acid-dissociative functional group which is dissociated by an acid to generate an acid functional group comprises a unit represented by the following formula (1): 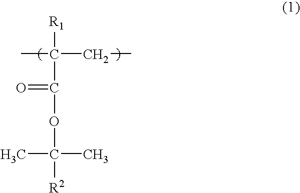
wherein R¹ is a hydrogen atom or a methyl group, and R² is a monovalent alicyclic group of 6 to 20 carbon atoms which may have a substituent or a monovalent aromatic group of 6 to 20 carbon atoms which may have a substituent.

6. The positive type radiation-sensitive resin composition for producing a product formed by plating as claimed in claim 4, wherein a repeating unit having the acid-dissociative functional group in the polymer (A) having an acid-dissociative functional group which is dissociated by an acid to generate an acid functional group comprises a unit represented by the following formula (1): 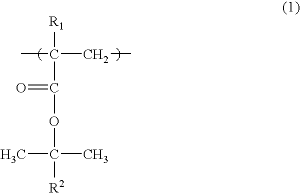
wherein R¹ is a hydrogen atom or a methyl group, and R² is a monovalent alicyclic group of 6 to 20 carbon atoms which may have a substituent or a monovalent aromatic group of 6 to 20 carbon atoms which may have a substituent.

7. A process for producing a product formed by plating, comprising:
(a) a step of forming a resin film wherein the positive type radiation-sensitive resin composition for producing a product formed by plating of any one of claims 1 to 6 is applied onto a substrate having a conductive layer on its surface and then dried,
(b) a step of forming a pattern wherein the resin film is irradiated with a radiation in a given pattern configuration, then heated and developed,
(c) a step wherein a product formed by plating is formed in a given thickness by electroplating with the use of the pattern formed on the substrate as a mold,
(d) a step wherein the resin film is removed from the substrate, and
(e) a step wherein the conductive layer present on the area of the substrate other than the area where the product formed by plating has been formed is removed.

8. A positive type radiation-sensitive resin film for producing a product formed by plating, comprising a resin film formed by applying the positive type radiation-sensitive resin composition for producing a product formed by plating of any one of claims 1 to 6 onto a support film, drying the composition and then peeling the support film.

9. A process for producing a product formed by plating, comprising:
(a) a step wherein the positive type radiation-sensitive resin film for producing a product formed by plating of claim 8 is laminated on a substrate having a conductive layer on its surface,
(b) a step of forming a pattern wherein the resin film laminated is irradiated with a radiation in a given pattern configuration, then heated and developed,
(c) a step wherein a product formed by plating is formed in a given thickness by electroplating with the use of the pattern formed on the substrate as a mold,
(d) a step wherein the resin film is removed from the substrate, and
(e) a step wherein the conductive layer present on the area of the substrate other than the area where the product formed by plating has been formed is removed.

10. The process for producing a product formed by plating as claimed in claim 7, wherein the thickness of the resin film formed or laminated on the substrate is in the range of 20 to 100 μm.

11. The process for producing a product formed by plating as claimed in claim 9, wherein the thickness of the resin film formed or laminated on the substrate is in the range of 20 to 100 μm.
